(19) United States
(12) Patent Application Publication
(10) Pub. No.: US 2025/0087465 A1
(43) Pub. Date: Mar. 13, 2025

(54) RING ASSEMBLY FOR SEMICONDUCTOR PROCESS, SUBSTRATE PROCESSING APPARATUS INCLUDING THE SAME, AND METHOD OF MANUFACTURING SEMICONDUCTOR DEVICE USING THE SAME

(71) Applicant: Samsung Electronics Co., Ltd., Suwon-si (KR)

(72) Inventor: Hyungsik Ko, Suwon-si (KR)

(21) Appl. No.: 18/598,037

(22) Filed: Mar. 7, 2024

(30) Foreign Application Priority Data
Sep. 7, 2023 (KR) 10-2023-0118910

(51) Int. Cl. H01J 37/32; H01L 21/67; H01L 21/683

(52) U.S. Cl. CPC H01J 37/32642; H01J 37/32449; H01J 37/32724; H01L 21/67248; H01L 21/6831; H01J 2237/2007; H01J 2237/334

(57) ABSTRACT

Provided is a substrate processing apparatus including a chamber, an electrostatic chuck (ESC) in the chamber and configured to support a substrate, a shower head in the chamber and on the electrostatic chuck, and a ring assembly for a semiconductor process in the chamber and surrounding the electrostatic chuck, wherein the ring assembly for the semiconductor process includes a focus ring having a central axis extending in a first direction, an outer ring surrounding the focus ring, and a top ring on a top surface of the outer ring.

### CROSS-REFERENCE TO RELATED APPLICATIONS

This U.S. non-provisional patent application claims priority under 35 U.S.C. § 119 to Korean Patent Application No. 10-2023-0118910, filed on Sep. 7, 2023, in the Korean Intellectual Property Office, the entire contents of which are hereby incorporated by reference.

### BACKGROUND OF THE INVENTION

The inventive concept relates to a ring assembly for semiconductor process, a substrate processing apparatus including the same, and a method of manufacturing a semiconductor device using the same, and in detail relates to a ring assembly for semiconductor process capable of protecting an outer ring, a substrate processing apparatus including the same, and a method of manufacturing a semiconductor device using the same

Semiconductor devices may be manufactured through various processes. For example, semiconductor devices may be manufactured through a photo process, an etching process, a deposition process, and so on. In an etching process for manufacturing a semiconductor device, plasma may be used. In a wafer etching process using plasma, a ring assembly for semiconductor process may be used to control distribution of plasma.

### SUMMARY

An object of the inventive concept is to provide a ring assembly for semiconductor process capable of reducing a deposition amount of polymer, a substrate processing apparatus including the same, and a method of manufacturing a semiconductor device using the same.

The problem to be solved by the inventive concept is not limited to the problems mentioned above, and other problems not mentioned will be clearly understood by those skilled in the art from the description below.

A substrate processing apparatus according to some embodiments of the inventive concept may include a chamber, an electrostatic chuck (ESC) in the chamber and configured to support a substrate, a shower head in the chamber and on the electrostatic chuck, and a ring assembly for a semiconductor process in the chamber and surrounding the electrostatic chuck, wherein the ring assembly for the semiconductor process may include a focus ring having a central axis extending in a first direction, an outer ring surrounding the focus ring; and a top ring on a top surface of the outer ring.

A substrate processing apparatus including a ring assembly, wherein the ring assembly according to some embodiments of the inventive concept may include a focus ring having a central axis extending in a first direction, an outer ring surrounding the focus ring, and a top ring on the outer ring, wherein a top surface of the focus ring may have a first inner diameter, and a bottom surface of the focus ring may have a second inner diameter, the first inner diameter may be smaller than the second inner diameter, an inner surface of the focus ring may include a first inner surface and a second inner surface, and an angle formed by the first inner surface with the first direction may be different from an angle formed by the second inner surface with the first direction.

Specific details of other embodiments are included in the detailed description and drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a substrate processing apparatus according to embodiments of the inventive concept.

FIG. 2 is an enlarged view illustrating an electrostatic chuck, focus ring, outer ring, and top ring according to embodiments of the inventive concept, and is an enlarged view of region X of FIG. 1.

FIG. 3 is a perspective view illustrating a semiconductor ring assembly according to embodiments of the inventive concept.

FIGS. 4 to 6 are enlarged views for illustrating an electrostatic chuck and a focus ring according to embodiments of the inventive concept, and are enlarged views of region X′ of FIG. 2.

FIG. 7 is an enlarged view for illustrating a top ring according to embodiments of the inventive concept, and is an enlarged view of region Y of FIG. 2.

FIG. 8 is a flowchart illustrating a method of manufacturing a semiconductor device according to embodiments of the inventive concept.

FIGS. 9 to 11 are cross-sectional views sequentially illustrating the method of manufacturing a semiconductor device according to the flowchart of FIG. 8.

### DETAILED DESCRIPTION

Hereinafter, embodiments of the inventive concept will be described with reference to the attached drawings. The same reference numerals may refer to the same elements throughout the specification.

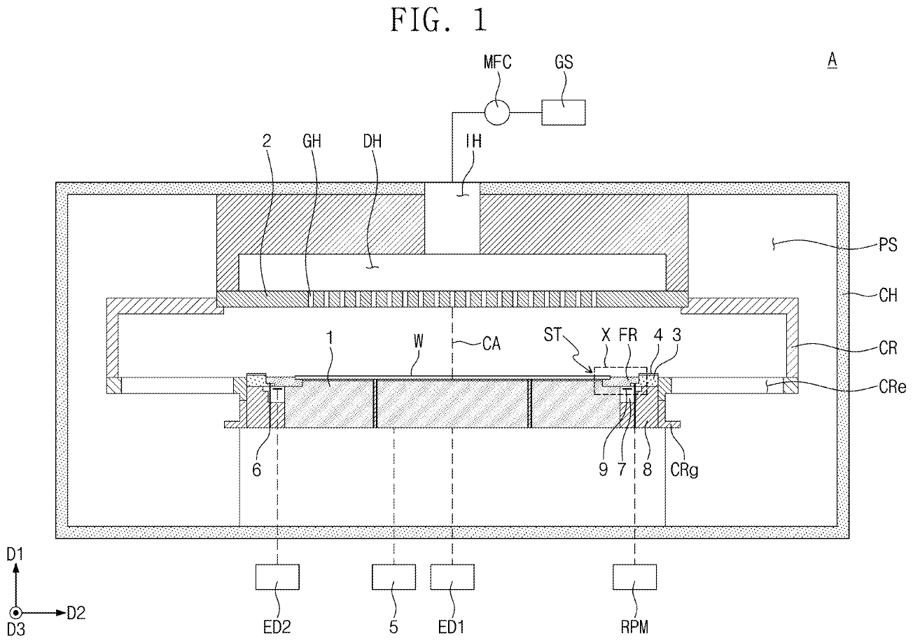

FIG. 1 is a cross-sectional view illustrating a substrate processing apparatus according to embodiments of the inventive concept.

Hereinafter, D1 in FIG. 1 may be referred to as a first direction, D2 crossing or perpendicular to the first direction D1 may be referred to as a second direction, and D3 crossing or perpendicular to each of the first direction D1 and the second direction D2 may be referred to as a third direction. The first direction D1 may be referred to as an upward direction, and a direction opposite to the first direction D1 may be referred to as a downward direction. Alternatively, the first direction D1 may be referred to as a vertical direction. Additionally, each of the second direction D2 and the third direction D3 may be referred to as a horizontal direction.

Referring to FIG. 1, a substrate processing apparatus A may be provided. The substrate processing apparatus A may be a device for etching a substrate. In detail, the substrate processing apparatus A may refer to a device that etches one side of a substrate using plasma. The substrate processing apparatus A may generate plasma in various ways. For example, the substrate processing apparatus A may generate plasma using a method such as Capacitively Coupled Plasma (CCP), Inductively Coupled Plasma (ICP), or Magnetically Enhanced RIE (MERIE). However, it is not limited thereto, and the substrate processing apparatus A may etch the substrate using other methods. Below, for convenience, the substrate processing apparatus A will be described based on CCP.

The substrate processing apparatus A may include a chamber CH, a gas supplier or gas supply GS, a shower head 2, a temperature controller 5, a confinement ring CR, a stage ST, a ring lift pin driver RPM, a first RF power supplier ED1 and a second RF power supplier ED2.

The chamber CH may provide or define a process space PS. The stage ST may be disposed in the process space PS. A substrate W may be placed on the stage ST in the chamber CH. While the stage ST is disposed in the process space PS, an etching process for the substrate W may be performed.

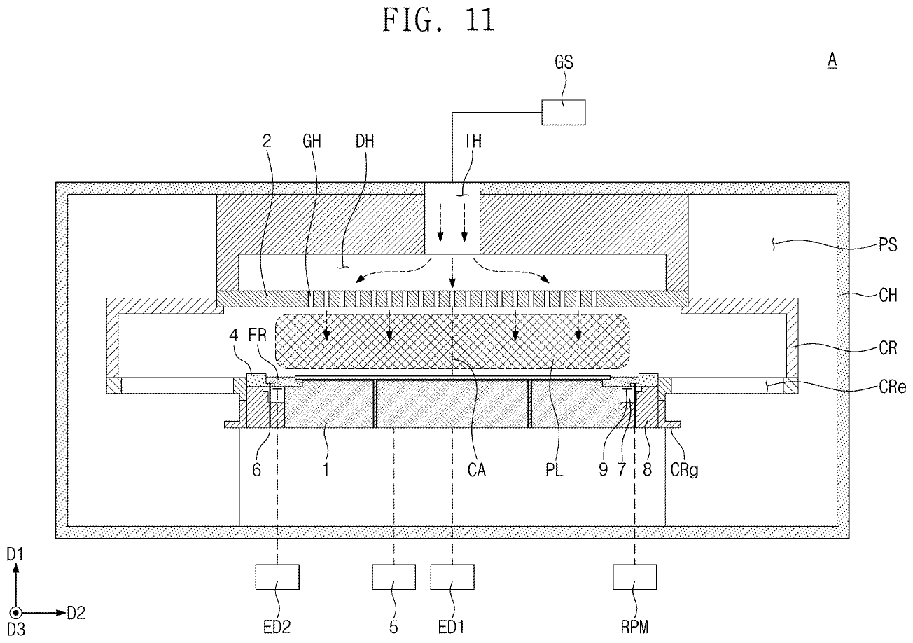

The gas supplier GS may be disposed outside the chamber CH and may be connected to the chamber CH. For example, the gas supplier GS may be connected to the process space PS through a gas inlet IH. The gas supplier GS may supply process gas that becomes plasma PL (see, e.g., FIG. 11). To this end, the gas supplier GS may include a gas tank and a compressor. The gas supplier GS may include a mass flow controller MFC. The mass flow controller may electrically control a flow rate of gas supplied from the gas supplier GS.

The shower head 2 may be coupled to an upper part of the chamber CH. A distribution space DH may be provided on the shower head 2. The distribution space DH may be connected to the gas supplier GS through the gas inlet IH. The shower head 2 may provide an outlet GH. When viewed in a plan view, distribution holes GH may be arranged in the second direction D2 and the third direction D3. Process gas supplied from the gas supplier GS may be supplied onto the stage ST through the distribution holes GH. A bottom surface of the shower head 2 may have a planar shape, but is not limited thereto. That is, the bottom surface of the shower head 2 may have a winding curved shape, unlike that illustrated in FIG. 1.

The confinement ring CR may surround a space on the shower head 2 and the stage ST. The confinement ring CR may provide or include a slit CRe. Gas on the stage ST may exhaust uniformly downward through the slit CRe. A plurality of slits CRe may be provided.

The stage ST may be disposed in the chamber CH. The substrate W may be placed on the stage ST. The stage ST may include an electrostatic chuck 1, a focus ring FR, a coupling ring 7, an outer ring 3, a ground ring 8, a top ring 4 and a ring lift pin 6.

The electrostatic chuck 1 may support and/or fix the substrate W. For example, when the substrate W is placed on the electrostatic chuck 1, the electrostatic chuck 1 may fix the substrate W in a certain position using electrostatic force. The temperature controller 5 may be coupled inside the electrostatic chuck 1. The temperature controller 5 may control a temperature of the electrostatic chuck 1. That is, the temperature controller 5 may lower the temperature of the overheated electrostatic chuck 1 using a refrigerant. To this end, the temperature controller 5 may include a cooler. Details about the electrostatic chuck 1 will be described below.

The focus ring FR may surround the substrate W placed on the electrostatic chuck 1. The focus ring FR may be a rotating body based on a central axis CA. However, it is not limited thereto. The central axis CA of the focus ring FR may extend in the first direction D1. The focus ring FR may include silicon (Si) and/or silicon carbide (SiC). However, it is not limited thereto, and the focus ring FR may include other materials. The focus ring FR may be separated into two or more members. The two or more members of the focus ring FR may include different materials. Details about this will be described below.

The coupling ring 7 may be disposed below the focus ring FR. The coupling ring 7 may surround the electrostatic chuck 1. In detail, when viewed in a plan view, the coupling ring 7 may surround the electrostatic chuck 1 from the outside. The coupling ring 7 may include alumina (Al₂O₃).

The outer ring 3 may surround the electrostatic chuck 1. That is, the outer ring 3 may be a rotating body based on the central axis CA. The outer ring 3 may be positioned on the ground ring 8 and the coupling ring 7. The outer ring 3 may include quartz. However, it is not limited thereto.

The ground ring 8 may surround the coupling ring 7. The ground ring 8 may support the outer ring 3, for example.

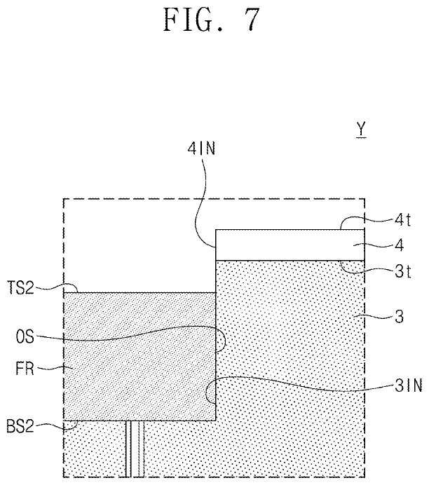

The top ring 4 may be positioned on the outer ring 3. The top ring 4 may surround the electrostatic chuck 1. That is, the top ring 4 may be a rotating body based on the central axis CA. The top ring 4 may completely cover a top surface (3t, refer to FIG. 7) of the outer ring 3. The top ring 4 may include a different material than the outer ring 3. For example, the top ring 4 may include silicon (Si). More details about the top ring 4 will be described below.

The ring lift pin 6 may extend in the first direction D1. The ring lift pin 6 may be disposed on the outside of the electrostatic chuck 1. The ring lift pin 6 may penetrate at least a portion of the outer ring 3 upward and downward. The ring lift pin 6 may be moved up and down by the ring lift pin driver RPM. The ring lift pin 6 may move up and down and may load or unload a portion of the focus ring FR. A plurality of ring lift pins 6 may be provided. For example, three ring lift pins 6 may be provided. The plurality of ring lift pins 6 may be arranged to be spaced apart from each other in the horizontal or circumferential direction. However, hereinafter, for convenience, the ring lift pin 6 will be described in the singular.

The ring lift pin driver RPM may move the ring lift pin 6 up and down. To this end, the ring lift pin driver RPM may include an actuator such as an electric motor and/or a hydraulic motor.

The first RF power supplier ED1 may be electrically connected to the electrostatic chuck 1. The first RF power supplier ED1 may transmit first RF power to the electrostatic chuck 1.

The second RF power supplier ED2 may be electrically connected to the outer electrode 9. The second RF power supplier ED2 may transmit second RF power to the outer electrode 9. The second RF power may be different from the first RF power.

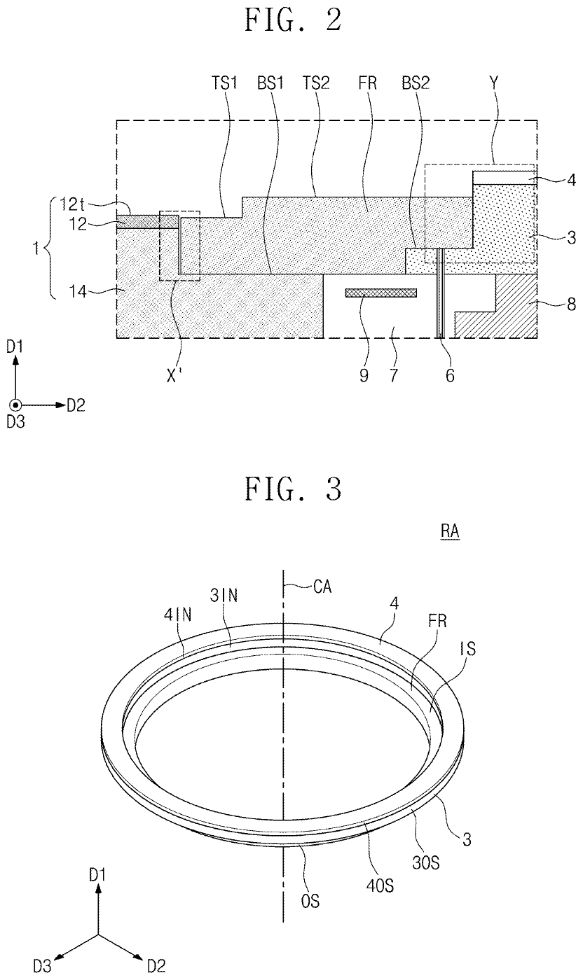

FIG. 2 is an enlarged view illustrating the electrostatic chuck 1, focus ring FR, outer ring 3, and top ring 4 according to embodiments of the inventive concept, and is an enlarged view of region X of FIG. 1.

Referring to FIG. 2, the electrostatic chuck 1 may further include a plasma electrode 14 and a chuck 12.

The plasma electrode 14 may support the chuck 12. The plasma electrode 14 may be connected to the first RF power supplier ED1. The plasma electrode 14 may receive first RF power from the first RF power supplier ED1. The plasma electrode 14 may include a conductive material. For example, the plasma electrode 14 may include aluminum. When the substrate processing apparatus A (refer to FIG. 1) is a CCP device, the plasma electrode 14 may be a lower electrode. Additionally, the shower head 2 (refer to FIG. 1) may be an upper electrode. The plasma electrode 14 may have a cylindrical shape.

The chuck 12 may be positioned on plasma electrode 14. The substrate W may be provided on a top surface 12t of the chuck 12. That is, the chuck 12 may support and fix the substrate W while being in contact with the substrate W. A plurality of burl structures may be provided on the top surface 12t of the chuck 12 to support the substrate W. The chuck 12 may include an electrode. The electrode may use electrostatic force to fix the substrate W at a certain position on the chuck.

The coupling ring 7 may include an outer electrode 9. The outer electrode 9 may be disposed below the focus ring FR and may be disposed in the coupling ring 7. The outer electrode 9 may be spaced apart from the ring lift pin 6. The outer electrode 9 may include tungsten and/or platinum. The outer electrode 9 may be electrically connected to the second RF power supplier ED2 of FIG. 1. The outer electrode 9 may receive the second RF power from the second RF power supplier ED2.

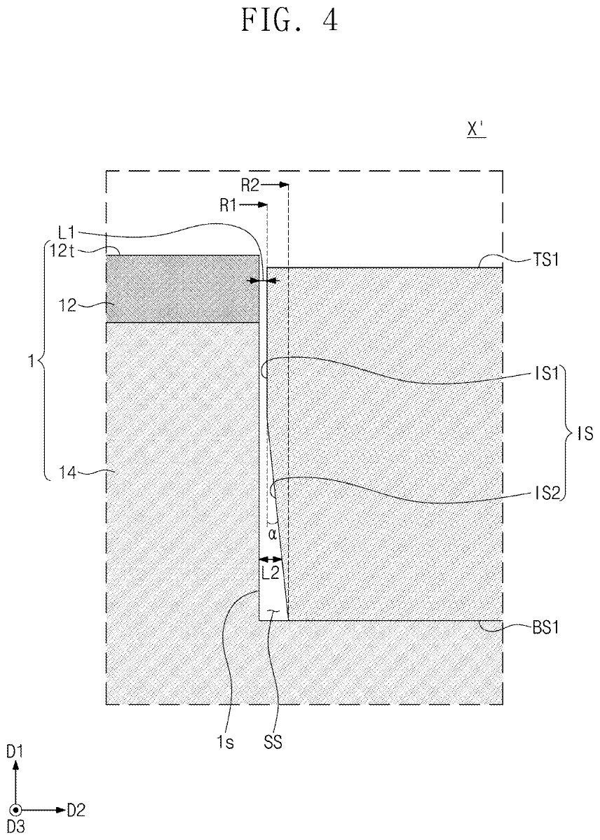

Upper and bottom surfaces of the focus ring FR may have a step difference. That is, the top surface of the focus ring FR may include a first top surface TS1 and a second top surface TS2 at different levels. The bottom surface of the focus ring FR may include a first bottom surface BS1 and a second bottom surface BS2 at different levels. The first top surface TS1 may be positioned at a lower level than the second top surface TS2. The first bottom surface BS1 may be positioned at a lower level than the second bottom surface BS2. An inner surface IS (refer to FIG. 4) of the focus ring FR may be disposed between the first top surface TS1 and the first bottom surface BS1. An outer surface OS (refer to FIG. 7) of the focus ring FR may be disposed between the second top surface TS2 and the second bottom surface BS2. The focus ring FR may be disposed on the electrostatic chuck 1, the coupling ring 7 and the outer ring 3. In detail, the first bottom surface BS1 of the focus ring FR may be positioned on the same plane as an exposed top surface of the plasma electrode 14 and the top surface of the coupling ring 7. The second bottom surface BS2 of the focus ring FR may be disposed on a portion of the outer ring 3. The first top surface TS1 of the focus ring FR may be positioned at a lower level than the top surface 12t of the chuck 12. Therefore, when the substrate W is positioned on the electrostatic chuck 1, the substrate W may not be in contact with the first top surface TS1 of the focus ring FR. The second top surface TS2 of the focus ring FR may be disposed at a lower level than the top surface 3t of the outer ring 3 (refer to FIG. 7). However, the inventive concept is not limited thereto. That is, the first top surface TS1 of the focus ring FR may be disposed on the same plane or at a higher level than the top surface 12t of the chuck 12. The second top surface TS2 of the focus ring FR may be disposed on the same plane as a top surface 3t of the outer ring 3 or may be higher than the top surface 3t of the outer ring 3.

The ring lift pin 6 may be disposed below the focus ring FR. The ring lift pin 6 may be in contact with the second bottom surface BS2 of the focus ring FR. The ring lift pin 6 may be disposed outside the outer electrode 9. That is, the ring lift pin 6 may not overlap the outer electrode 9 when viewed in a plan view. The ring lift pin 6 may penetrate the ground ring 8 up and down. The ring lift pin 6 may penetrate the coupling ring 7 up and down. Therefore, a pin insertion hole extending upward and downward may be provided in the coupling ring 7. The ring lift pin 6 may be disposed in the pin insertion hole and may move up and down.

FIG. 3 is a perspective view illustrating a ring assembly RA for a semiconductor process according to embodiments of the inventive concept.

Referring to FIG. 3, a ring assembly RA for semiconductor process may be provided.

The ring assembly RA for semiconductor process may include a focus ring FR, an outer ring 3, and a top ring 4. That is, the focus ring FR, outer ring 3, and top ring 4 described with reference to FIGS. 1 and 2 may be collectively referred to as a ring assembly RA for semiconductor process. The focus ring FR may be a rotating body having a central axis CA extending in the first direction D1. An inner surface IS of the focus ring FR may face the central axis CA. The inner surface IS of the focus ring FR may define a space through which the central axis CA passes. An outer surface OS of the focus ring FR may face a direction opposite to the central axis CA. An inner diameter of the focus ring FR may mean the maximum distance between the inner surfaces IS of the focus ring FR. An outer diameter of the focus ring FR may mean the maximum distance between the outer surfaces OS of the focus ring FR. That is, a distance from the central axis CA to the inner surface IS of the focus ring FR may be half of the inner diameter of the focus ring FR. A distance from the central axis CA to the outer surface OS of the focus ring FR may be half of the outer diameter of the focus ring FR.

The outer ring 3 may be a rotating body having the central axis CA extending in the first direction D1. An inner surface 3IN of the outer ring 3 may face the central axis CA. An outer surface 3OS of the outer ring 3 may face in a direction opposite to the central axis CA. An inner diameter of the outer ring 3 may mean the maximum distance between the inner surfaces 3 IN of the outer ring 3. An outer diameter of the outer ring 3 may mean the maximum distance between the outer surfaces 3OS of the outer ring 3. That is, a distance from the central axis CA to the inner surface 3 IN of the outer ring 3 may be half the inner diameter of the outer ring 3. The outer diameter or the outer surface 3OS of the outer ring 3 may protrude further radially outward than the outer diameter or the outer surface OS of the focus ring FR. A distance between the inner diameter or the inner surface 3IN of the outer ring 3 and the central axis CA may not be closer (or may be further) than the distance between the inner diameter or the inner surface IS of the focus ring FR and the central axis CA.

The top ring 4 may be a rotating body having the central axis CA extending in the first direction D1. An inner surface 4 IN of the top ring 4 may face the central axis CA. An outer surface 4OS of the top ring 4 may face in a direction opposite to the central axis CA. An inner diameter of the top ring 4 may mean the maximum distance between the inner surfaces 4 IN of the top ring 4. An outer diameter of the top ring 4 may mean the maximum distance between the outer surfaces 4OS of the top ring 4. That is, a distance from the central axis CA to the inner surface 4 IN of the top ring 4 may be half the inner diameter of the top ring 4. The top ring 4 may include silicon (Si) material. However, it is not limited thereto, and the top ring 4 may include a material different from that of the outer ring 3. A bottom surface of the top ring 4 may be in contact with the top surface 3t of the outer ring 3. A distance between the inner surface 4IN of the top ring 4 and the central axis CA may be the same as the distance between the inner surface 3IN of the outer ring 3 and the central axis CA. The top ring 4 may overlap the outer ring 3. However, it is not limited thereto. The top ring 4 and the focus ring FR may cover the entire top surface 3t of the outer ring 3. Therefore, the top surface 3t of the outer ring 3 may not be exposed. The top ring 4 may not overlap the focus ring FR, but is not limited thereto.

FIGS. 4 to 6 are enlarged views for illustrating the electrostatic chuck 1 and the focus ring FR according to embodiments of the inventive concept, and are enlarged views of region X′ of FIG. 2.

Referring to FIG. 4, the inner surface IS of the focus ring FR may include a first inner surface IS1 and a second inner surface IS2. The inner surface IS of the focus ring FR may be disposed between the first top surface TS1 and the first bottom surface BS1 of the focus ring FR. The first inner surface IS1 of the focus ring FR may be disposed between the first top surface TS1 and the first bottom surface BS1 or the second inner surface IS2 of the focus ring FR. The first inner surface IS1 may be perpendicular to the first top surface TS1. That is, an angle between the first inner surface IS1 and the first top surface TS1 may be 90°. In other words, the first inner surface IS1 may be parallel to the first direction D1, and an angle formed by the first inner surface IS1 with the first direction D1 may be 0°. Additionally, an angle formed by the first inner surface IS1 with the first direction D1 may be different from the angle formed by the second inner surface IS2 with the first direction D1. The first top surface TS1 of the focus ring FR may be disposed at a lower level than the top surface of the electrostatic chuck 1. The second inner surface IS2 may extend from the first inner surface IS1. That is, the second inner surface IS2 may be in contact with the first inner surface IS1 and may be disposed between the first inner surface IS1 and the first bottom surface BS1. The second inner surface IS2 and the first inner surface IS1 may share a circumference of one circle at the point where the second inner surface IS2 and the first inner surface IS1 interface or are in contact with each other. The second inner surface IS2 may form a constant angle a with the first direction D1. That is, the angle a formed by the second inner surface IS2 with the first direction D1 may be different from the angle formed by the first inner surface IS1 with the first direction D1. The second inner surface IS2 may not be parallel to the first direction D1. The second inner surface IS2 may not be perpendicular to the first top surface TS1 or the first bottom surface BS1. The angle a formed by the second inner surface IS2 and the first direction D1 or vertical may be an acute angle. For example, the angle a formed by the second inner surface IS2 with the first direction D1 may be greater than about 1° and less than or equal to about 5°, but is not limited thereto. The first top surface TS1 may have a first inner diameter R1. The first bottom surface BS1 may have a second inner diameter R2. The first inner diameter R1 may be smaller than the second inner diameter R2. That is, the first top surface TS1 may be closer to the electrostatic chuck 1 than the first bottom surface BS1. A distance between the first inner surface IS1 and a side surface 1S of the electrostatic chuck 1 may be a first distance L1. A distance between the second inner surface IS2 and the side surface 1S of the electrostatic chuck 1 may increase from the first top surface TS1 to the first bottom surface BS1. An average distance between the second inner surface IS2 and the side surface 1S of the electrostatic chuck 1 may be a second distance L2. The first distance L1 may be smaller than the second distance L2. That is, the first inner surface IS1 may be closer to the side surface Is of the electrostatic chuck 1 than the second inner surface IS2. A spare space SS may be provided between the side surface Is and the second inner surface IS2 of the focus ring FR.

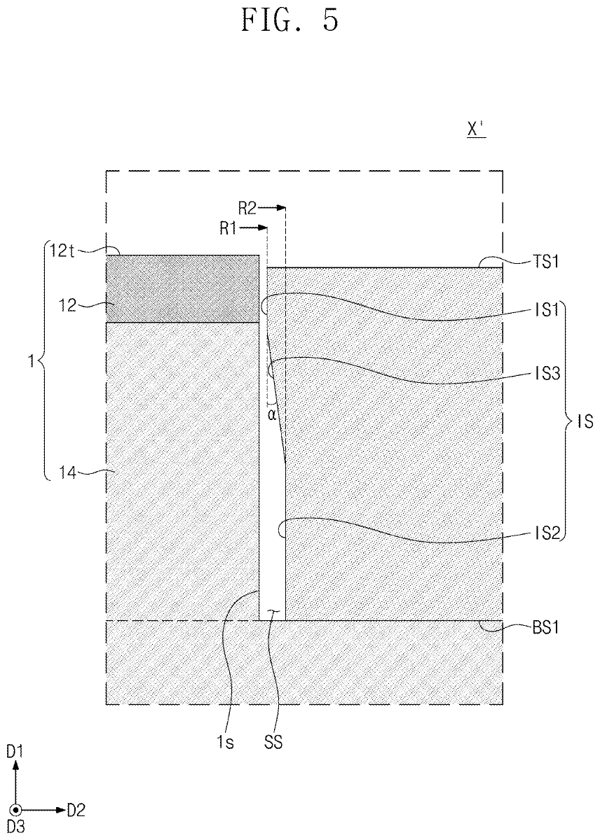

Referring to FIG. 5, the inner surface IS of the focus ring FR may further include a third inner surface IS3. The third inner surface IS3 may be disposed between the first inner surface IS1 and the second inner surface IS2. That is, the third inner surface IS3 may extend downward from the first inner surface IS1, and the second inner surface IS2 may extend downward from the third inner surface IS3. The first inner surface IS1 and the third inner surface IS3 may share a perimeter or circumference of one circle, and the third inner surface IS3 and the second inner surface IS2 may share a circumference of another circle. The first inner surface IS1 and the second inner surface IS2 may be parallel to the first direction D1. That is, the first inner surface IS1 and the second inner surface IS2 may be perpendicular to the first top surface TS1 or the first bottom surface BS1. The first inner surface IS1 and the second inner surface IS2 may be parallel to each other. The third inner surface IS3 may form a constant angle a with the first direction D1 or vertical. The third inner surface IS3 may not be parallel to the first direction D1. The angle a formed by the third inner surface IS3 and the first direction D1 may be an acute angle. For example, the angle a formed by the third inner surface IS3 with the first direction D1 may be greater than 1° and approximately 5° or less, but is not limited thereto. For example, the second inner surface IS2 may be parallel to the first direction D1, and the angle formed by the second inner surface IS2 with the first direction D1 may be different from the angle formed by the third inner surface IS3 with the first direction D1. The first inner surface IS1 may be closer to the side surface Is of the electrostatic chuck 1 than the second inner surface IS2 and the third inner surface IS3. The second inner surface IS2 may be spaced further apart from the side surface Is of the electrostatic chuck 1 than the first inner surface IS1 and the third inner surface IS3.

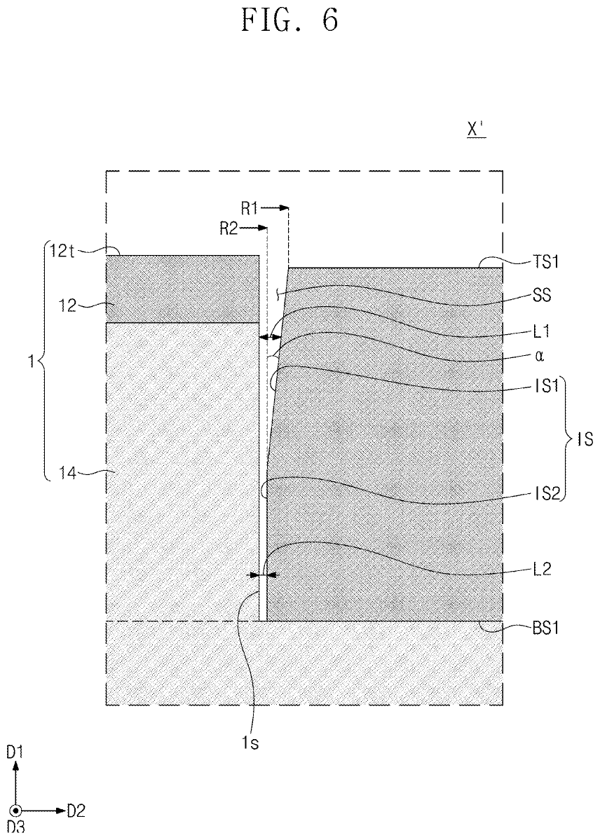

Referring to FIG. 6, the inner surface IS of the focus ring FR may be disposed between the first top surface TS1 and the first bottom surface BS1, and may include a first inner surface IS1 and a second inner surface IS2. The second inner surface IS2 may extend from the first inner surface IS1, and the second inner surface IS2 and the first inner surface IS1 may share a circumference of one circle at the point where and the second inner surface IS2 and the first inner surface IS1 interface or are in contact with each other. The first inner surface IS1 may form a constant angle a with the first direction D1 or vertical. That is, the first inner surface IS1 may not be parallel to the first direction D1. The angle a formed between the first inner surface IS1 and the first direction DI may be an acute angle. For example, the angle a formed between the first inner surface IS1 and the first direction D1 may be greater than 1° and less than or equal to about 5°, but is not limited thereto. Accordingly, a distance between the first inner surface IS1 and the side surface Is of the electrostatic chuck 1 may become closer from the first top surface TS1 to the first bottom surface BS1. An average distance between the first inner surface IS1 and the side surface Is of the electrostatic chuck 1 may be a first distance L1. The second inner surface IS2 may be parallel to the first direction D1. Accordingly, a distance between the second inner surface IS2 and the side surface 1s of the electrostatic chuck 1 may be constant. A distance between the second inner surface IS2 and the side surface 1s of the electrostatic chuck 1 may be a second distance L2. The second distance L2 may be smaller than the first distance L1. The first top surface TS1 may have a first inner diameter R1. The first bottom surface BS1 may have a second inner diameter R2. The first inner diameter R1 may be larger than the second inner diameter R2.

FIG. 7 is an enlarged view for illustrating the top ring 4 according to embodiments of the inventive concept, and is an enlarged view of region Y of FIG. 2.

Referring to FIG. 7, the top ring 4 may be positioned in contact with the top surface 3t of the outer ring 3. The top ring 4 may be disposed at a higher level than the focus ring FR. That is, a top surface 4t of the top ring 4 may be disposed at a higher level than the second top surface TS2 of the focus ring FR. An inner surface 4IN of the top ring 4 may not be in contact with the outer surface OS of the focus ring FR. A top surface 4t of the top ring 4 may be perpendicular to the outer surface OS of the focus ring FR or the inner surface 3IN of the outer ring 3. That is, an angle between the top surface 4t of the top ring 4 and the outer surface OS of the focus ring FR or the inner surface 3IN of the outer ring 3 may be 90°. That is, the top surface 4t of the top ring 4 may be perpendicular to the first direction D1, and the angle between the top surface 4t of the top ring 4 and the first direction DI may be 90°. The top surface 4t of the top ring 4 may be parallel to the second bottom surface BS2 of the focus ring FR or the top surface 3t of the outer ring 3.

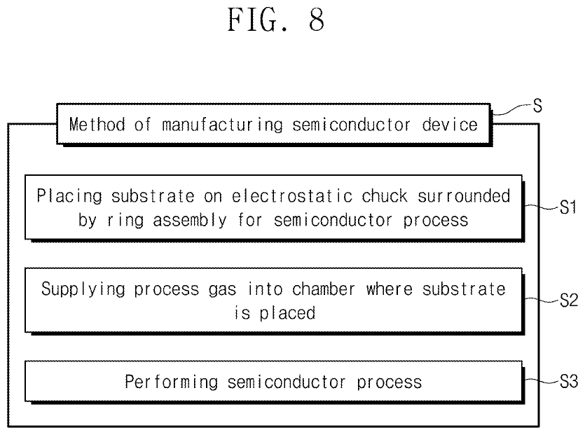

FIG. 8 is a flowchart illustrating a method S of manufacturing a semiconductor device according to embodiments of the inventive concept.

Referring to FIG. 8, a method S of manufacturing a semiconductor device may be provided. The method S of manufacturing a semiconductor device may be a method of manufacturing a semiconductor device using the substrate processing apparatus described in FIG. 1. To this end, the method S of manufacturing a semiconductor device may include placing a substrate W on an electrostatic chuck 1 surrounded by a ring assembly RA for semiconductor process in S1, supplying process gas into a chamber CH where the substrate W is placed in S2, and performing the semiconductor process in S3.

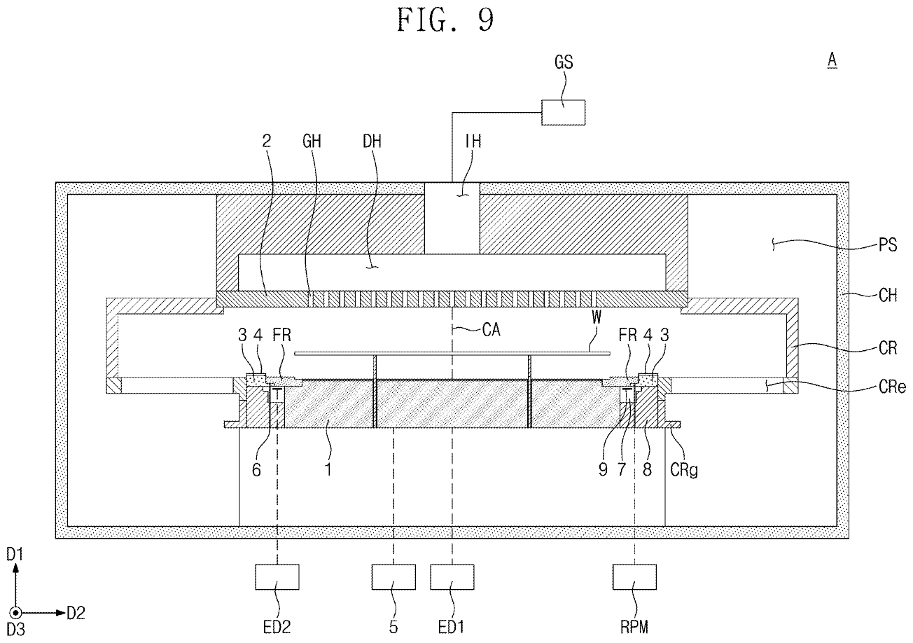

Hereinafter, the method S of manufacturing a semiconductor device of FIG. 8 will be described with reference to FIGS. 9 to 11.

FIGS. 9 to 11 are cross-sectional views sequentially illustrating the method of manufacturing a semiconductor device according to the flowchart of FIG. 8. Referring to FIG. 9, placing the substrate W on the electrostatic chuck 1 surrounded by the ring assembly RA for the semiconductor process in S1 may include placing the substrate W on a substrate lift pin elevated by a substrate lift pin driver. The substrate W may refer to a silicon wafer, but is not limited thereto. The substrate W may be brought into the chamber CH by a robot arm or the like. The robot arm may place the substrate W on the substrate lift pin.

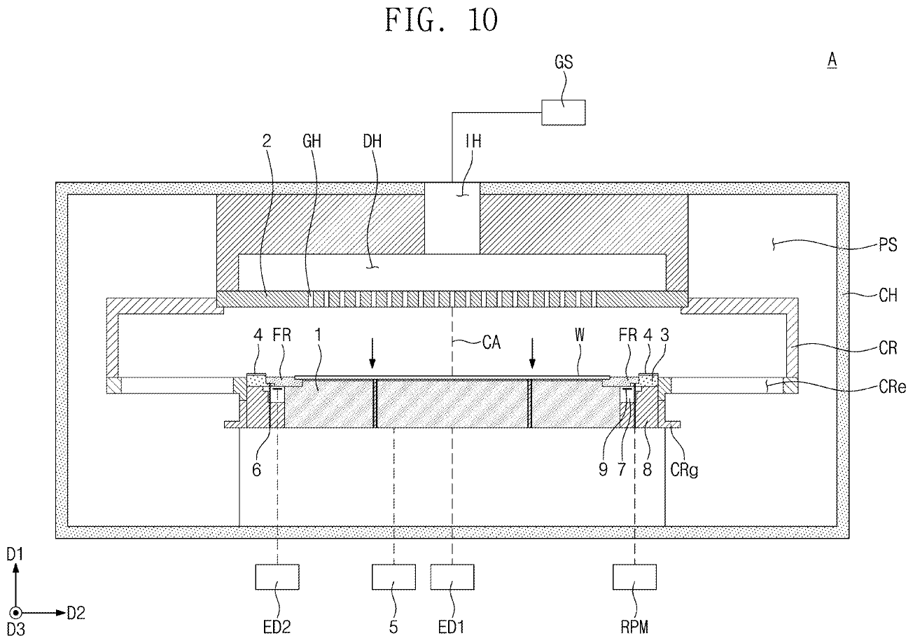

Referring to FIG. 10, the substrate lift pin may be lowered by the substrate lift pin driver. The substrate W may be placed on the electrostatic chuck 1. In detail, the substrate W may be seated on a top surface of the electrostatic chuck 1. The electrostatic chuck 1 may fix the substrate W at a certain position using electrostatic force provided by the electrode of the chuck 12.

Referring to FIG. 11, supplying the process gas into the chamber CH in which the substrate W is disposed in S2 may include supplying the process gas into the chamber CH by a gas supplier GS. In detail, the process gas may move onto the substrate W through a gas inlet IH, a distribution space DH, and distribution holes GH of a shower head 2. Thereafter, the process gas may move down a chamber CH through a slit CRe of a confinement ring CR and be discharged to the outside. The distribution holes GH of the shower head 2 may be arranged two-dimensionally when viewed in a plan view. Therefore, the process gas may be uniformly supplied to the substrate W.

Performing the semiconductor process in S3 may include supplying first RF power to a plasma electrode 14 and supplying second RF power to an outer electrode 9. Supplying the first RF power to the plasma electrode 14 may be performed by a first RF power supplier ED1. The plasma electrode 14 to which the first RF power is applied may form an electric field in a space on the substrate W. Plasma PL may be formed in the space on the substrate W due to the electric field and the process gas. For example, the semiconductor process may be a semiconductor process using plasma PL, and in detail, may be an etching process using plasma PL. Accordingly, a portion of a top surface of the substrate W may be etched by the plasma PL.

According to the ring assembly for semiconductor process of the inventive concept, the substrate processing apparatus including the same, and the method of manufacturing the semiconductor device using the same, the electrostatic chuck of the substrate processing apparatus may be surrounded by the ring assembly for semiconductor process. The semiconductor ring assembly may include the focus ring, the outer ring, and the top ring. The top ring may be disposed on the outer ring. The top ring may cover the entire upper surface of the outer ring. Accordingly, polymer deposition on the upper surface of the outer ring may be prevented. That is, the ring assembly for semiconductor process may reduce the amount of polymer deposited on the outer ring. Accordingly, substrate production efficiency may be increased.

According to the ring assembly for semiconductor process of the inventive concept, the substrate processing apparatus including the same, and the method of manufacturing the semiconductor device using the same, the deposition amount of polymer during the process may be reduced.

According to the ring assembly for semiconductor process of the inventive concept, the substrate processing apparatus including the same, and the method of manufacturing a semiconductor device using the same, the process efficiency of the etching process may be increased.

The effects of the inventive concept are not limited to the effects mentioned above, and other effects not mentioned will be clearly understood by those skilled in the art from the description above.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A substrate processing apparatus comprising:
a chamber;
an electrostatic chuck (ESC) in the chamber and configured to support a substrate;
a shower head in the chamber and on the electrostatic chuck; and
a ring assembly for a semiconductor process in the chamber and surrounding the electrostatic chuck,
wherein the ring assembly for the semiconductor process includes:
a focus ring having a central axis extending in a first direction;
an outer ring surrounding the focus ring; and
a top ring on a top surface of the outer ring.

2. The substate processing apparatus of claim 1, further comprising a gas supplier connected to the chamber,
wherein the gas supplier is configured to inject a process gas onto the electrostatic chuck.

3. The substate processing apparatus of claim 1, further comprising a temperature controller configured to control a temperature of the substrate placed on the electrostatic chuck.

4. The substate processing apparatus of claim 2, wherein the gas supplier includes a mass flow controller configured to electrically control a flow rate of the process gas.

5. The substate processing apparatus of claim 1, wherein a top surface of the focus ring is positioned at a lower vertical level than a top surface of the electrostatic chuck.

6. The substate processing apparatus of claim 1, wherein the electrostatic chuck includes a plasma electrode configured to generate plasma.

7. The substate processing apparatus of claim 1, wherein an inner surface of the focus ring includes a first inner surface and a second inner surface,
wherein the first inner surface extends from one of a top surface of the focus ring and a bottom surface of the focus ring to the second inner surface of the focus ring,
wherein the second inner surface of the focus ring extends from the first inner surface of the focus ring to the other one of the top surface of the focus ring and the bottom surface of the focus ring, and
wherein the first inner surface is closer to the electrostatic chuck than the second inner surface.

8. The substate processing apparatus of claim 7, wherein an angle formed by the first inner surface with the first direction is different from an angle formed by the second inner surface with the first direction.

9. The substate processing apparatus of claim 1, wherein a top surface of the focus ring has a first inner diameter,
wherein a bottom surface of the focus ring has a second inner diameter, and
wherein the first inner diameter is smaller than the second inner diameter.

10. The substate processing apparatus of claim 1, wherein the top ring includes a silicon (Si) material.

11. The substate processing apparatus of claim 7, wherein the first inner surface of the focus ring is parallel to the first direction, and
wherein the second inner surface of the focus ring is at an acute angle with the first direction.

12. The substate processing apparatus of claim 11, wherein the acute angle is greater than 1° and less than or equal to 5°.

13. The substate processing apparatus of claim 1, wherein the top ring includes a material different from the outer ring.

14. A substrate processing apparatus comprising a ring assembly, wherein the ring assembly comprises:
a focus ring having a central axis extending in a first direction;
an outer ring surrounding the focus ring; and
a top ring on the outer ring;
wherein a top surface of the focus ring has a first inner diameter, and a bottom surface of the focus ring has a second inner diameter,
wherein the first inner diameter is smaller than the second inner diameter,
wherein an inner surface of the focus ring includes a first inner surface and a second inner surface, and
wherein an angle formed by the first inner surface with the first direction is different from an angle formed by the second inner surface with the first direction.

15. The substate processing apparatus of claim 14, wherein the first inner surface of the focus ring is parallel to the first direction, and
wherein the second inner surface of the focus ring forms an acute angle with the first direction.

16. The substate processing apparatus of claim 14, wherein the top ring and the focus ring cover an entire top surface of the outer ring, and the top surface of the outer ring is not exposed.

17. The substate processing apparatus of claim 14, wherein the focus ring includes Si or silicon carbide (SiC),
wherein the outer ring includes quartz, and
wherein the top ring includes silicon (Si).

18. The substate processing apparatus of claim 14, wherein the top ring does not vertically overlap the focus ring.

19. The substate processing apparatus of claim 15, wherein the acute angle is greater than 1° and less than or equal to 5°.

20. The substate processing apparatus of claim 14, wherein the top ring includes a material different from the outer ring.
